(19) United States
(12) Patent Application Publication
(10) Pub. No.: US 2008/0017900 A1
(43) Pub. Date: Jan. 24, 2008

(54) CMOS IMAGE SENSOR

(76) Inventor: Hyun-Soo Shin, Seoul (KR)

Correspondence Address: SHERR & NOURSE, PLLC, 620 HERNDON PARKWAY, SUITE 200, HERNDON, VA, 20170, US

(21) Appl. No.: 11/781,036

(22) Filed: Jul. 20, 2007

(30) Foreign Application Priority Data
Jul. 21, 2006 (KR) 10-2006-0068304

(51) Int. Cl. H01L 31/113; H01L 31/18

(52) U.S. Cl. 257/290; 438/59; 257/E31.083

(57) ABSTRACT

A complementary metal oxide semiconductor (CMOS) sensor may include a substrate and a device isolation layer formed above the substrate. A nitride layer is formed between the device isolation layer and the substrate. An n type impurity region is formed in a photodiode region of the substrate. A p type impurity region is formed in the photodiode region on the n type impurity region. A gate oxide layer and a gate electrode are formed on the substrate to form a gate stack.

The present application claims priority under 35 U.S.C. 119 and 35 U.S.C. 365 to Korean Patent Application No. 10-2006-0068304 (filed on Jul. 21, 2006), which is hereby incorporated by reference in its entirety.

### BACKGROUND

Image sensors may be semiconductor devices to convert optical images into electric signals. Examples of image sensors may include a charge coupled device (CCD) and a CMOS image sensor.

In a CCD, charge carriers may be stored in and transferred between metal oxide semiconductor (MOS) capacitors that may be densely arranged. A CMOS image sensor may be a switching device which may include as many MOS transistors as there are pixels, and may be formed based on CMOS technology. A CMOS sensor may use a control circuit and a signal processing circuit as peripheral circuits. The CMOS image senor may detect an object using the MOS transistors.

In each pixel of a CMOS image sensor, a photodiode and a MOS transistor may be formed to detect a signal corresponding to an image pixel by a switching method. In this manner, a CMOS image sensor may create an image corresponding to an object. As described above, since the CMOS sensor may be fabricated using CMOS technology, only about twenty masks may be required to fabricate the CMOS image senor while thirty to forty masks may be required to fabricate the CCD. That is, the CMOS image senor may be fabricated through a more simple process.

FIG. 1 is a circuit diagram schematically illustrating a pixel structure of a CMOS image sensor, and FIGS. 2 to 4 are drawings illustrating a method of fabricating a CMOS image sensor.

Referring to FIG. 1, pixel 100 of a CMOS image sensor may include photodiode 110 as a photodetector, reset transistor Rx 120, driver transistor Dx 130, and select transistor Sx 140.

Reset transistor Rx 120 may carry an optical charge that may be generated by photodiode 110 and may discharge for signal detection. Driver transistor Dx 130 may be used as a source follower. Select transistor Sx 140 may be used for switching and addressing.

A method of fabricating a CMOS image sensor will now be described with reference to FIGS. 2 to 4.

Referring to FIG. 2, device isolation layer 121 may be formed in p type semiconductor substrate 101 through a shallow trench isolation (STI) process. Gate insulation layer 122 and gate electrode 123 may be sequentially formed on p type semiconductor substrate 101. Device isolation layer 121 may be formed of an oxide.

Dopant ions, such as n type dopant ions, may be implanted into p type semiconductor substrate 101 and may form an impurity region n− in p type semiconductor substrate 101.

Referring to FIG. 3, photoresist pattern 125 may be formed on p type semiconductor substrate 101. Photoresist pattern 125 may cover the impurity region n−. An impurity region may be formed using photoresist pattern 125 as an ion implantation mask to form a lightly doped drain (LDD) structure in a drain region beside gate electrode 123.

Referring to FIG. 4, spacers 126 may be formed on both sides of gate electrode 123, and a p type impurity region p^{o} may be formed in the n type impurity region n− and may form a photodiode. A heavily-doped impurity region n+ may be formed at the drain region by selectively implanting dopant ions.

Since device isolation layer 121 may be formed of an oxide, the impurity regions doped with an n type dopant may be stressed by device isolation layer 121 as shown by arrows in FIG. 4.

Due to stress that may be caused by device isolation layer 121 formed of an oxide, the CMOS image senor may deteriorate, and thus the CMOS image sensor may not be reliably used.

### SUMMARY

Embodiments relate to a complementary metal oxide semiconductor (CMOS) image sensor, and relate to a CMOS image sensor that may reduce stress caused by an oxide in an inactive region and a method of fabricating the CMS image sensor.

Embodiments may provide a complementary metal oxide semiconductor (CMOS) image sensor having a structure that may restrict a stress caused by a device isolation layer, and a method of fabricating the CMOS image sensor.

In embodiments, a CMOS sensor may include a substrate, a device isolation layer above the substrate, a nitride layer between the device isolation layer and the substrate, an n type impurity region in a photodiode region of the substrate, a p type impurity region in the photodiode region on the n type impurity region, and a gate oxide layer and a gate electrode on the substrate to form a gate stack.

According to embodiments, dopants implanted into the substrate may not be concentrated into the device isolation layer, and thus the CMOS image sensor can operate more reliably.

### DRAWINGS

FIG. 1 is a circuit diagram schematically illustrating a pixel structure of a complementary metal oxide semiconductor (CMOS) image sensor.

FIGS. 2 to 4 are drawings illustrating a method of fabricating a CMOS image sensor.

FIG. 5 is a drawing illustrating a CMOS image sensor according to embodiments.

FIGS. 6 to 12 are drawings illustrating a method of fabricating a CMOS image sensor according to embodiments.

FIGS. 13 and 14 are drawings illustrating a method of fabricating a CMOS image senor according to embodiments.

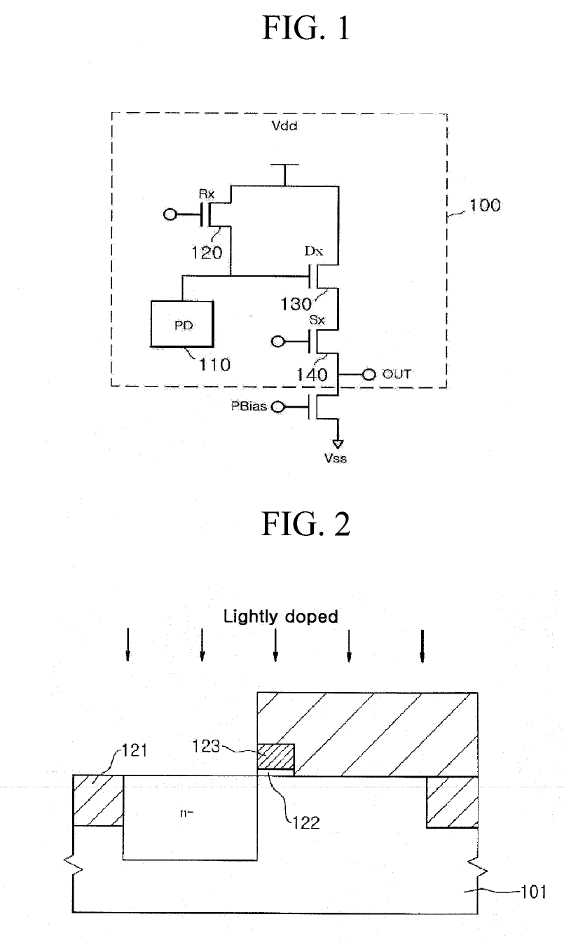

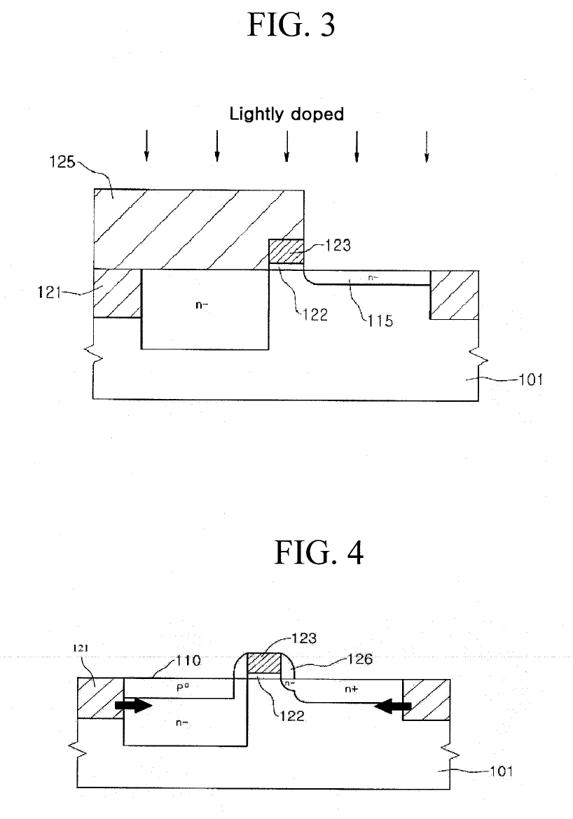

### DETAILED DESCRIPTION

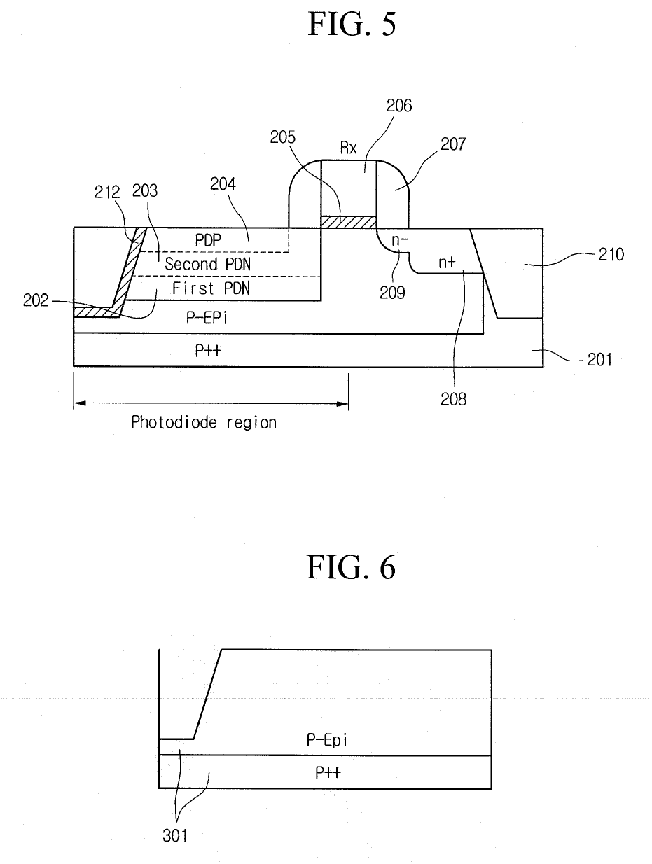

Referring to FIG. 5, a CMOS image sensor according to embodiments may include gate oxide layer 205 formed on semiconductor substrate 201 in which a heavily doped layer P++ and a p-type epitaxial layer P-EPi may be stacked. It may further include reset gate 206 formed on gate oxide layer 205. A shallow trench isolation may be formed in semiconductor substrate 201 and may be device isolation layer 210.

According to embodiments, nitride layer 212 may be formed under device isolation layer 210 by deposition. Nitride layer 212 may prevent the device isolation layer 210 from stressing impurity regions of semiconductor substrate 201.

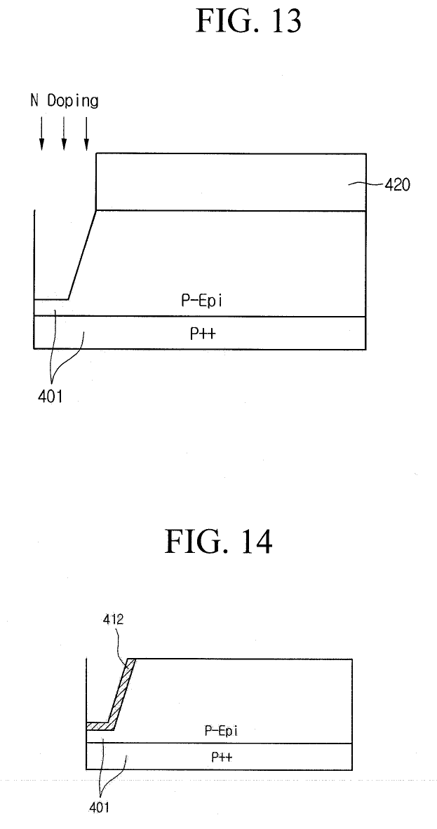

In embodiments, nitride layer 212 may be formed under device isolation layer 210 and may prevent device isolation layer 210 from stressing impurity regions of semiconductor substrate 201. However, in embodiments, a region of semiconductor substrate 201 where device isolation layer 210 may be formed may be doped with a dopant instead of forming nitride layer 212, as shown in FIGS. 13 and 14.

An impurity region (hereinafter, referred to as a PDN region) may be formed in a photodiode region located at a side of reset gate 206 in a two-layer structure and may form a photodiode.

A depletion layer may be formed in the PDN region when impurity molecules may be concentrated on a surface portion of semiconductor substrate 201. In embodiments, to prevent generation of the depletion layer, the PDN region may be formed into a two-layer structure that may include n type impurity region (hereinafter, referred to as a first PDN region) 202 doped with phosphor (P) and n type impurity region (hereinafter, referred to as a second PDN region) 203 doped with arsenic As. p type impurity region (hereinafter, referred to as a PDP region) 204 doped with a p+ type impurity may be formed on second PDN region 203.

In embodiments, second PDN region 203 and PDP region 204 may prevent a dark current occurring when impurity molecules implanted into first PDN region 202 may be diffused to semiconductor substrate 201.

Furthermore, n+ region 208 may be formed in semiconductor substrate 201 at the other side of reset gate 206, and spacers 207 may be formed on both sides of reset gate 206.

n− region 209 may be formed under one of spacers 207 adjacent to n+ region 208. n+ region 208 and n− region 209 form an LDD structure.

A silicide layer (not shown) may be formed on a region (a logic region) of the CMOS image sensor other than the photodiode region. The silicide layer may increase a speed of transistors by reducing the resistance of the transistors.

FIGS. 6 to 12 are drawings illustrating a method of fabricating a CMOS image sensor according to embodiments.

Referring to FIG. 6, substrate 301 in which a heavily doped P++ layer and a P-EPi layer may be stacked may be prepared. An inactive region of substrate 301 may be etched to a predetermined depth to form a trench for a device isolation layer.

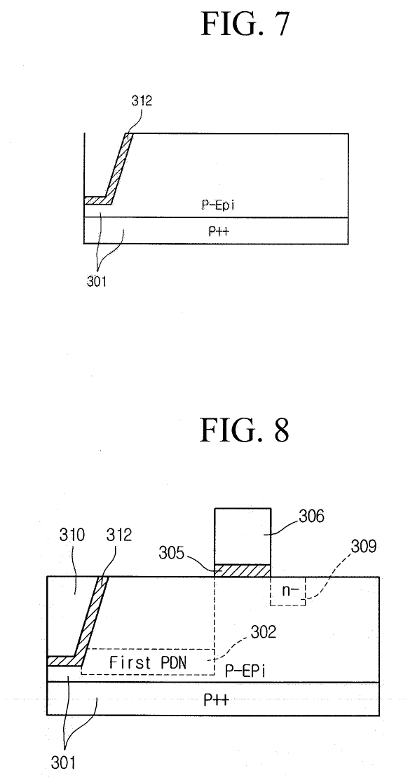

Referring to FIG. 7, nitride layer 312 may be deposited on the trench to a predetermined thickness.

In embodiments, nitride layer 312 may be deposited in the temperature range of 600° C. to 800° C. at a pressure of 0.1 to 200 Torr using SiH2Cl2 at a flowrate of 0.1 to 10 SLM and NH3 at a flowrate of 0.1 to 10 SLM. In embodiments, nitride layer 312 may thus be formed to a thickness of 0.1 nm to 5 nm.

Instead of forming the nitride layer 312, an n type dopant may be implanted into the trench for the same purpose. This will be described with reference to FIGS. 13 and 14.

Owing to nitride layer 312, a stress may not be transmitted from a device isolation layer to impurity regions of substrate 301.

Referring to FIG. 8, device isolation 310 may be formed on substrate 301 by thermal oxidation, according to embodiments. Gate oxidation layer 305 and gate electrode 306 may be sequentially stacked on substrate 301 to form a gate stack.

An n type dopant may be implanted into a lower portion of a photodiode region of substrate 301 and may use gate electrode 306 as an ion implantation mask.

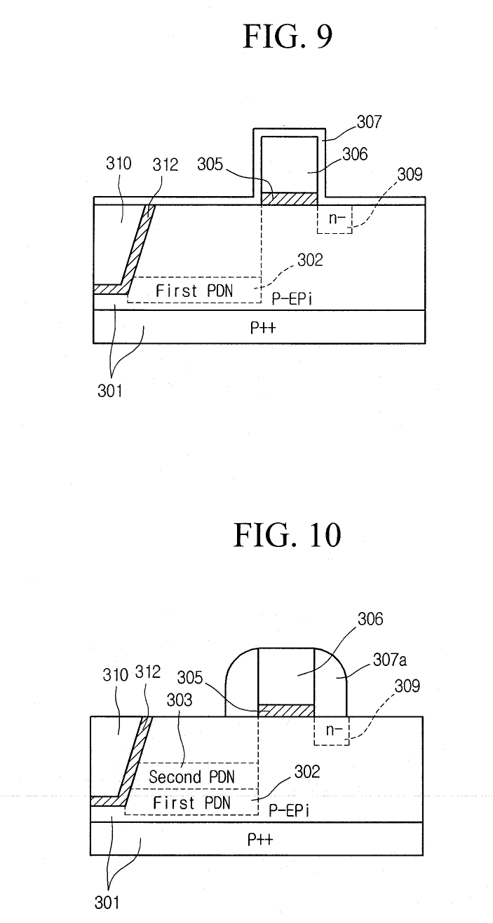

Referring to FIG. 9, insulation layer 307 may be formed on a surface, for example, the entire surface, of substrate 301 and may form spacers. Insulation layer 307 may include a 200-Å SiO2 layer and a 800-Å SiN layer that may be sequentially stacked on substrate 301.

Referring to FIG. 10, insulation layer 307 may be selectively etched away to form spacers 307a on both sides of the gate stack.

A dopant may be implanted into substrate 301 using spacers 307a as an ion implantation mask to form second PDN region 303.

An n type dopant such as arsenic (As) may be implanted into substrate 301 at a rate of 1.0×10¹² [atoms/cm²] in the ion implantation energy range of 200±50 keV to form second PDN region 303 on first PDN region 302.

In embodiments, second PDN region 303 may be formed after first PDN region 302 may be formed. However, second PDN region 303 may be formed before first PDN region 302 may be formed by adjusting the amount of dopant ions and the ion implantation energy in an ion implantation process.

For the same reason, a PDP region (described later) may be formed after or before first and second PDN regions 302 and 303 may be formed, according to embodiments.

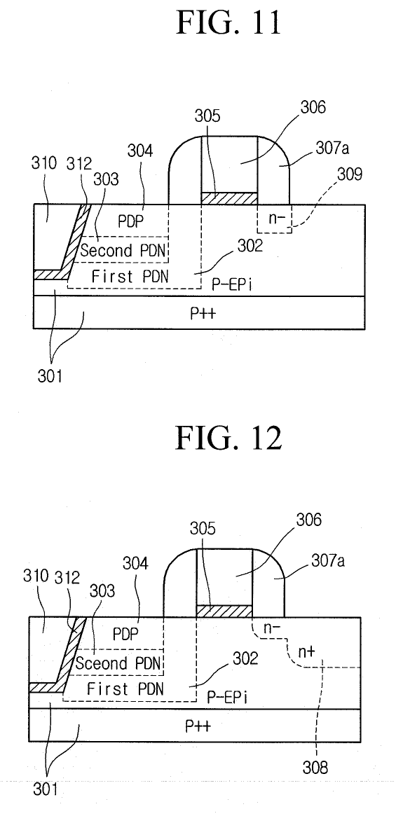

Referring to FIG. 11, a p type dopant may be implanted into substrate 301 using spacers 307a as an ion implantation mask to form PDP region 304 on second PDN region 303.

Therefore, the heavily doped P++ region, the P-EPi layer formed by epitaxial growth, first PDN region 302 doped with an n type dopant, second PDN region 303 formed on first PDN region 302 and doped with an n type dopant, and PDP region 304 formed on second PDN region 303 may be included in the photodiode region of substrate 301.

Referring to FIG. 12, a dopant may be implanted in a logic region of substrate 301 except for the photodiode region to a high concentration, and may use spacers 307 as a mask to form n+ region 308 that may be formed into heavily doped source/drain regions of a transistor.

Although not shown, a silicide layer may be formed on the logic region of substrate 301.

FIGS. 13 and 14 are drawings illustrating a method of fabricating a CMOS image senor according embodiments.

In other embodiments, nitride layer 312 may be formed to a predetermined thickness in the trench of substrate 301 where device isolation layer 310 may be formed using an oxide. However, in embodiments, the trench may be doped with a dopant instead of forming nitride layer 312.

In embodiments, referring to FIG. 13, substrate 401, in which a heavily doped P++ layer and a P-EPi layer may be stacked, may be prepared. An inactive region of the substrate 401 may be etched away to a predetermined depth to form a trench for a device isolation layer.

Photoresist layer 420 may be formed on substrate 401, and dopant ions may be implanted into the trench.

In embodiments, the dopant ions implanted into the trench of substrate 401 may be nitride ions. In embodiments, the nitride ions may be implanted in the temperature range from room temperature to 600° C. at a power of 10 to 500 W under a pressure of 0 to 50 Torr at an ion flowrate of 0.1 to 10 SLM.

Referring to FIG. 14, impurity-doped region 412 may be formed in the trench as a result of the nitride ion implantation.

Impurity-doped region 412 may have the same function as nitride region 312 of the other embodiments. The following processes of embodiments may be the same as those of other embodiments.

According to embodiments, n type dopant molecules may not be concentrated from the PDN region to a surface of the substrate. Furthermore, the impurity regions of the substrate such as the PDN region and the PDP region may be less stressed owing to the oxide used to form the device isolation layer.

Therefore, dopant molecules may not be moved from the impurity regions to the device isolation layer by a stress acting on the impurity regions by the device isolation layer.

Furthermore, the PDN region may be formed by implanting different n type dopants. In embodiments, the first and second PDN regions of the PDN region may be formed using different dopants at different ion implantation energies. Therefore, the phosphor (P) implanted into the first PDN region may be stably positioned.

In embodiments, the first PDN region, the second PDN region, and the PDP region may be sequentially formed. However, the first PDN region, the second PDN region, and the PDP region may be formed in a different order.

According to embodiments, implanted dopant molecules may not be concentrated into the device isolation layer, and thus the CMOS image sensor may operate more reliably.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A device, comprising:
a substrate;
a device isolation layer over the substrate;
one of a nitride layer between the device isolation layer and the substrate and an impurity-doped region formed by doping a portion of the substrate adjacent to the device isolation layer with nitride; and
an impurity region in a photodiode region of the substrate.

2. The device of claim 1, wherein the impurity region comprises a first impurity region in the photodiode region of the substrate and a second impurity region in the photodiode region over the first impurity region.

3. The device of claim 2, further comprising a gate oxide layer and a gate electrode on the substrate to form a gate stack.

4. The device of claim 2, wherein the first impurity region comprises a plurality of layers doped with different first-type dopants.

5. The device of claim 2, wherein the first impurity region is doped with n-type dopants, and the second impurity region is dopoed with p-type dopants.

6. The device of claim 2, wherein the impurity-doped region is formed by implanting nitride into the portion of the substrate adjacent to the device isolation layer at a pressure of 0 to 50 Torr in a nitride-flowrate range of 0.1 to 10 SLM.

7. The device of claim 1, wherein the nitride layer comprises SiH₂Cl₂ and NH₃ formed to a thickness of 0.1 nm to 5 nm.

8. A method, comprising:
etching a substrate to form a trench in which a device isolation layer is to be formed;
depositing a nitride layer to a predetermined thickness over the trench of the substrate; and
forming the device isolation layer over the nitride layer.

9. The method of claim 8, further comprising:
forming a gate oxide layer over the semiconductor substrate;
forming a gate electrode over the gate oxide layer being;
implanting a first dopant into the substrate using the gate electrode as an ion implantation mask;
forming spacers on both sides of the gate electrode;
implanting the first dopant into the substrate using the spacers as an ion implantation mask; and
implanting a second dopant into the substrate.

10. The method of claim 9, wherein the nitride layer is deposited using SiH₂Cl₂ and NH₃ to a thickness of 0.1 nm to 5 nm.

11. The method of claim 9, wherein the first dopant is n-type dopant, and the second dopant is p-type dopant.

12. The method of claim 9, wherein the nitride is implanted into the substrate at a pressure of 0 to 50 Torr in a nitride-flowrate range of 0.1 to 10 SLM.

13. A method, comprising:
forming a trench in a substrate, the trench being configured to form a device isolation layer;
implanting nitride into the trench;
forming the device isolation layer over the nitride;
forming a gate oxide layer over the substrate;
forming a gate electrode over the gate oxide layer;
implanting a first dopant into the substrate using the gate electrode as an ion implantation mask;
forming spacers on both sides of the gate electrode;
implanting the first dopant into the substrate using the spacers as an ion implantation mask; and
implanting a second dopant into the substrate.

14. The method of claim 13, wherein the trench is formed by performing an etching process.

15. The method of claim 13, wherein the nitride is implanted at a pressure of 0 to 50 Torr in a nitride-flowrate range of 0.1 to 10 SLM.

16. The method of claim 13, wherein the first dopant comprises an n-type dopant, and the second dopant comprises a p-type dopant.

17. The method of claim 13, wherein the nitride layer is implanted by depositing SiH₂Cl₂ and NH₃ to a thickness of 0.1 nm to 5 nm.
